(19) United States
(12) Patent Application Publication
(10) Pub. No.: US 2025/0015059 A1
(43) Pub. Date: Jan. 9, 2025

(54) LIGHT-EMITTING DIODE DISPLAY DEVICE

(71) Applicant: Lextar Electronics Corporation, Hsinchu City (TW)

(72) Inventors: Chih-Hao LIN, Hsinchu City (TW); Chun-Xin YE, Hsinchu City (TW); Jin-Shing TSENG, Hsinchu City (TW)

(21) Appl. No.: 18/761,831

(22) Filed: Jul. 2, 2024

(30) Foreign Application Priority Data
Jul. 6, 2023 (TW) 112125207

(51) Int. Cl. H01L 25/075; G09G 3/32; H01L 33/60

(52) U.S. Cl. CPC H01L 25/0753; G09G 3/32; H01L 33/60; G09G 2320/0666

(57) ABSTRACT

A light-emitting diode display device is provided. The light-emitting diode display device includes a substrate and a plurality of green units, a plurality of red units, a plurality of blue units, and a plurality of cyan units periodically arranged on the substrate. The quantity of green units is higher than the quantity of red units, the quantity of green units is higher than the quantity of blue units, and the quantity of green units is higher than the quantity of cyan units.

### CROSS REFERENCE TO RELATED APPLICATIONS

This Application claims priority of Taiwan Patent Application No. 112125207, filed on Jul. 6, 2023, and the content of the entirety of which is incorporated by reference herein.

### BACKGROUND OF THE DISCLOSURE

### Field of the Disclosure

The present disclosure is related to a display device, and, in particular, it is related to a light-emitting diode display device.

### Description of the Related Art

In the existing light-emitting diode (LED) display technology, the function of displaying color images generally is realized by disposing red LED units, green LED units, and blue LED units in the display device and mixing the colors of the three types of LED units. Because the users' requirements for display devices are gradually increasing with the wide application of display devices, although existing light-emitting diode display devices have largely met the intended purposes, they do not meet the requirements placed on them in every respect.

### BRIEF SUMMARY OF THE DISCLOSURE

In some embodiments, a light-emitting diode display device is provided. The light-emitting diode display device includes a substrate and a plurality of green units, a plurality of red units, a plurality of blue units, and a plurality of cyan units periodically arranged on the substrate. The quantity of green units is greater than the quantity of red units, the quantity of green units is greater than the quantity of blue units, and the quantity of green units is greater than the quantity of cyan units.

The light-emitting diode display device of the present disclosure can be applied to various types of electronic devices. In order to make the features and advantages of the present disclosure more comprehensible, various embodiments are specially cited below, together with the accompanying drawings, to be described in detail as follows.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic top view showing the light-emitting diode display device according to some embodiments of the present disclosure.

FIG. 2 is a schematic cross-sectional view showing the light-emitting diode display device according to some embodiments of the present disclosure.

FIG. 3 is a schematic cross-sectional view showing the light-emitting diode display device according to other embodiments of the present disclosure.

FIG. 4 is a schematic cross-sectional view showing the light-emitting diode display device according to still other embodiments of the present disclosure.

FIG. 5 is a schematic cross-sectional view showing the light-emitting diode display device according to still other embodiments of the present disclosure.

FIG. 6 is a schematic cross-sectional view showing the light-emitting diode display device according to still other embodiments of the present disclosure.

FIG. 7 is a schematic diagram showing the color-sharing mechanism according to some embodiments of the present disclosure.

FIG. 8 is an enlarged schematic diagram showing the minimum repeat unit in FIG. 1.

FIG. 9 is a schematic diagram showing the operation flow of the light-emitting diode display device according to some embodiments of the present disclosure.

FIG. 10A and FIG. 10B are schematic diagrams showing the temporal sub-units according to some embodiments of the present disclosure.

FIG. 11 is a schematic diagram showing the minimum repeat unit and the spatial sub-units of the light-emitting diode display device according to other embodiments of the present disclosure.

FIG. 12 is a schematic diagram showing the minimum repeat unit and the spatial sub-units of the light-emitting diode display device according to still other embodiments of the present disclosure.

FIG. 13 is a schematic diagram showing the minimum repeat unit and the spatial sub-units of the light-emitting diode display device according to still other embodiments of the present disclosure.

FIG. 14 is a schematic diagram showing the minimum repeat unit and the spatial sub-units of the light-emitting diode display device according to still other embodiments of the present disclosure.

FIG. 15 is a schematic diagram showing the minimum repeat unit and the spatial sub-units of the light-emitting diode display device according to still other embodiments of the present disclosure.

### DETAILED DESCRIPTION OF THE DISCLOSURE

The following disclosure provides many different embodiments or examples for implementing the provided light-emitting diode display device. Specific examples of features and their configurations are described below to simplify the embodiments of the disclosure, but certainly not to limit the disclosure. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The directional terms mentioned herein, such as “up”, “down”, “left”, “right”, and similar terms refer to the directions of the drawings. Accordingly, the directional terms used is to illustrate, not to limit, the present disclosure.

In some embodiments of the present disclosure, terms about disposing and connecting, such as “disposing”, “connecting” and similar terms, unless otherwise specified, may refer to two features are in direct contact with each other, or may also refer to two features are not in direct contact with each other, wherein there is an additional connect feature between the two features. The terms about disposing and connecting may also include the case where both features are movable, or both features are fixed.

In addition, ordinal numbers such as “first”, “second”, and the like used in the specification and claims are configured to identify different features or to distinguish different embodiments or ranges, rather than to limit the number, the upper or lower limits of features, and are not intended to limit the order of manufacture or arrangement of features.

The terms “about”, “substantially”, or the like used herein generally means within 10%, within 5%, within 3%, within 2%, within 1%, or within 0.5% of a given value or a given range. The value given herein is an approximate value, that is, the meanings of “about” or “substantially” may still be implied without the specific descriptions of “about” or “substantially”.

Unless otherwise defined, all terms (including technical and scientific terms) used herein have the same meaning as commonly understood by one of ordinary skill in the art. It should be understood that these terms, such as those defined in commonly used dictionaries, should be interpreted as having meanings consistent with the background or context of the related technology and the present disclosure, and should not be interpreted in an idealized or overly formal manner, unless otherwise specified in the embodiments of the present disclosure.

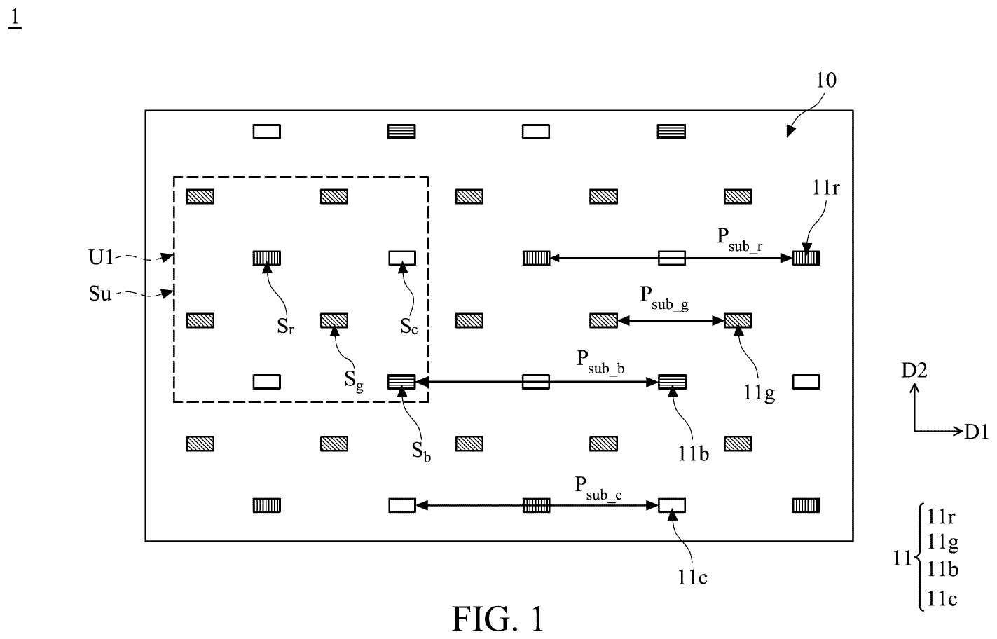

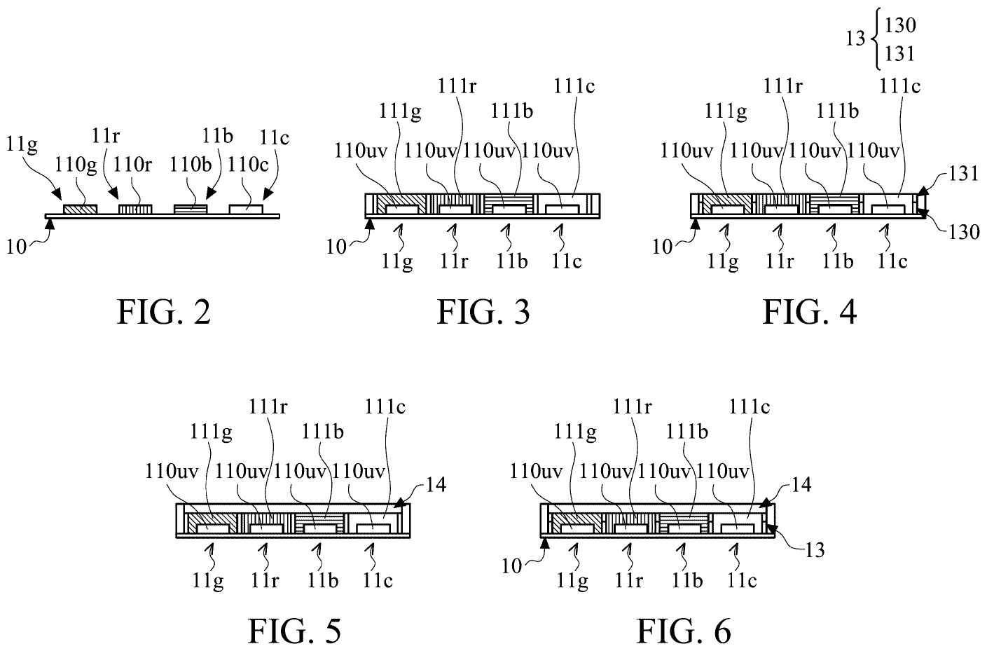

Referring to FIG. 1 and FIG. 2, which are respectively a schematic top view and a schematic cross-sectional view showing the light-emitting diode display device 1 according to some embodiments of the present disclosure. As shown in the figure, the light-emitting diode display device 1 includes a substrate 10 carrying electronic components (for example, the light-emitting units mentioned below) thereon. In some embodiments, the substrate 10 may be a printed circuit board (PCB), thin film transistor glass (TFT glass), complementary metal oxide semiconductor (CMOS) substrate, or other suitable substrates for carrying electronic components, but the present disclosure is not limited thereto.

In some embodiments, the light-emitting diode display device 1 further includes a light-emitting component 11. The light-emitting component 11 includes a plurality of green units 11g, a plurality of red units 11r, a plurality of blue units 11b, and a plurality of cyan units 11c, and the aforementioned light-emitting units are periodically arranged on the substrate 10 (the details will be explained below). In some embodiments, the green unit 11g, the red unit 11r, the blue unit 11b, and the cyan unit 11c have the same size. For example, the green unit 11g, the red unit 11r, the blue unit 11b, and the cyan unit 11c may have the same length, width, and thickness, but the present disclosure is not limited thereto. In some embodiments, the green unit 11g, the red unit 11r, the blue unit 11b, and the cyan unit 11c may have the same length and width (i.e., the same top view area) but have different thicknesses. The color gamut of the light-emitting diode display device may be improved by disposing the cyan units 11c in the light-emitting diode display device 1.

As shown in FIG. 2, in some embodiments, the green unit 11g may include a green LED chip 110g, and the green LED chip 110g may emit green visible light with a wavelength between 510 nm and 570 nm. The red unit 11r may include a red LED chip 110r, and the red LED chip 110r may emit red visible light with a wavelength between 610 nm and 750 nm. The blue unit 11b may include a blue LED chip 110b, and the blue LED chip 110b may emit blue visible light with a wavelength between 440 nm and 470 nm. The cyan unit 11c may include a cyan LED chip 110c, and the cyan LED chip 110c may emit cyan visible light with a wavelength between 470 nm and 510 nm. However, the present disclosure is not limited thereto.

Referring to FIG. 3, which is a schematic cross-sectional view showing the light-emitting diode display device 1 according to other embodiments of the present disclosure. As shown in the figure, in some embodiments, the light emitting units may include the same type of light emitting chips (for example, the same color) and different color conversion layers corresponding to the color of the light emitting units respectively, thereby achieving the same effect as described above. For example, each of the green unit 11g, the red unit 11r, the blue unit 11b, and the cyan unit 11c in FIG. 3 may include the ultraviolet LED chips 110uv and respectively include the green conversion layer 111g, the red conversion layer 111r, the blue conversion layer 111b, and the cyan conversion layer 111c disposed on the ultraviolet LED chips 110uv. The present disclosure may also use blue LED chips or LED chips of other colors (wavelengths) according to the requirements and is not limited to the above ultraviolet LED chips. The quantity of LED chips may be simplified by using LED chips of the same type.

In some embodiments, the materials of the LED chips may include inorganic semiconductor materials, such as III-V compounds, II-VI compounds, or other suitable materials for forming LED chips, but the present disclosure is not limited thereto. In some embodiments, each of the color conversion layers may include materials such as phosphor and quantum dots, so as to convert a color light emitted by each LED chip into a specific color light. For example, the cyan conversion layer 111c may include BaLu₂Al₂Ga₂SiO₁₂: Ce³⁺/Bi³⁺ which can convert the blue visible light emitted from a blue LED chip into the cyan visible light. For example, the cyan conversion layer 111c may include Ca₄₋₂ₓLiₓCeₓSi₂O₇F₂, Ca₂LuHf₂Al₃O₁₂:Ce³⁺, or a combination thereof which can convert the ultraviolet emitted from an ultraviolet LED chip into the cyan visible light. For example, the red conversion layer 111r or the green conversion layer 111g may include CdSe which can convert the ultraviolet emitted from an ultraviolet LED chip into the red visible light or the green visible light. For example, the blue conversion layer 111b may include CdS/ZnS which can convert the ultraviolet light emitted from an ultraviolet LED chip into the blue visible light. The above materials and combinations thereof are only examples, and the present disclosure may adopt any materials and combinations thereof known by a person having ordinary skills in the art to form the green unit 11g, the red unit 11r, the blue unit 11b, and the cyan unit 11c, and the present disclosure is not limited thereto.

Referring to FIG. 4, which is a schematic cross-sectional view showing the light-emitting diode display device according to still other embodiments of the present disclosure. As shown in the figure, in some embodiments, the light-emitting diode display device 1 may further include a plurality of spacers 13, and the spacers 13 are disposed between adjacent units (i.e. the green unit 11g, the red unit 11r, the blue unit 11b, and the cyan unit 11c to prevent two adjacent units from interfering with each other. In some embodiments, the spacer 13 includes a reflective wall 130 and an absorbing wall 131 disposed on the reflective wall 130. The reflective wall 130 may increase light utilization efficiency, and the absorbing wall 131 may reduce light leakage. In some embodiments, the reflective wall 130 may be white resin or metal that has reflective properties and may prevent leaking light. The white resin may include resin and light reflecting material. For example, the resin includes polymethyl methacrylate (PMMA), polyethylene terephthalate (PET), polystyrene (PS), polypropylene (PP), polyamide (PA), polycarbonate ester (PC), epoxy resin, or silicone resin, and the light-reflective material may be an oxide, such as TiO₂ or other suitable materials for reflecting light, but the present disclosure is not limited thereto. For example, the metal may be silver, aluminum, rhodium, silver, alloys thereof, or combinations thereof. In some embodiments, the absorbing wall 131 may include a black matrix resist that has light absorbing properties and improves color contrast. For example, the black matrix resist may be a chrome (Cr) metal black matrix resist, resin black matrix resist, graphite black matrix resist, or other suitable materials for absorbing light, but the present disclosure is not limited thereto. In some embodiments, the light transmittance of the reflective wall 130 or the absorbing wall 131 is less than 5%.

Referring to FIG. 5 and FIG. 6, which are schematic cross-sectional views showing the light-emitting diode display device according to other embodiments of the present disclosure. As shown in FIG. 5, in some embodiments, the light-emitting diode display device 1 may further include a distributed Bragg reflector (DBR) 14, and the distributed Bragg reflector 14 is disposed on the green units 11g, the red units 11r, the blue units 11b, and the cyan units 11c. Specifically, the distributed Bragg reflection layer 14 includes multiple layers stacked in sequence, and the multiple layers have different refractive indices. The distributed Bragg reflection layer 14 reflects the ultraviolet light that has not been completely converted into visible light to excite the red conversion layer 111r, the green conversion layer 111g, the blue conversion layer 111b, and the cyan conversion layer 111c again, thereby improving the conversion efficiency of each color conversion layer. As shown in FIG. 6, in some embodiments, the light-emitting diode display device 1 may be provided with a plurality of spacers 13 and a distributed Bragg reflection layer 14 at the same time, so as to further improve the optical characteristics of the light emitted by the LED chips.

Still referring to FIG. 1, in some embodiments, the green units 11g, the red units 11r, the blue units 11b, and the cyan units 11c are arranged along the first direction D1 and the second direction D2. The second direction D2 is perpendicular to the first direction D1. Since the human eye is more sensitive to green visible light, the density of pixel information seen by humans may be effectively increased by increasing the quantity of green units 11g. In other words, in the light-emitting diode display device 1 of the present disclosure, in order to provide a better display quality while realizing a wide color gamut, the quantity of green units 11g may be more than the quantity of red units 11r, the quantity of green units 11g may be more than the quantity of blue units 11b, and the quantity of green units 11g may be more than that of cyan units 11c.

In some embodiments, the density of pixel information seen by the human eye may be effectively increased by reducing the pitch between the green units 11g. As shown in FIG. 1, in the first direction D1, the minimum pitch P_{sub_g} between adjacent green units 11g may be less than the minimum pitch P_{sub_r} between adjacent red units 11r, the minimum pitch Pₛᵤ_g between adjacent green units 11g may be less than the minimum pitch P_{sub_b} between adjacent blue units 11b, and the minimum pitch P_{sub_g} between adjacent green units 11g may be less than the minimum pitch P_{sub_c} between two adjacent cyan units 11c.

As mentioned above, the recognition of color images by the human eye may be roughly divided into the color-sharing mechanism and the visual limit mechanism. When the human eye watches a display device, the color-sharing mechanism and the visual limit mechanism are related to the stripe pitch and the distance between the human eye and the display. When the stripe pitch is P and the distance between the human eye and the display is D, the angular frequency may be defined as

$$f ( P ) = \frac{1}{{tan}^{- 1} ( \frac{2 P}{D} )} .$$

On the other hand, the quantity of cycles of black and white stripes per degree of viewing angle that may be recognized by the human eye is defined as the spatial frequency, and the unit of the spatial frequency is CPD (cycles per degree). When the angular frequency (f(P)) satisfies a specific spatial frequency (CPD), the aforementioned color-sharing mechanism and visual limit mechanism may be realized. In other words, the effects of color-sharing and light mixing may be achieved by adjusting the minimum pitch between adjacent units.

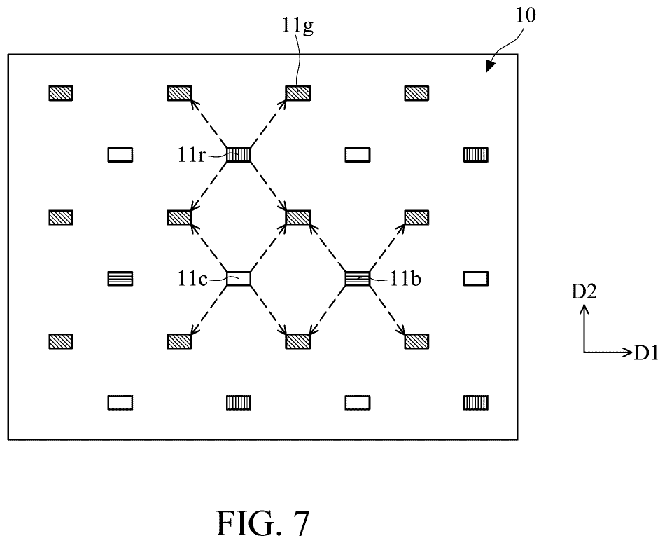

Referring to FIG. 1 and FIG. 7 at the same time, wherein FIG. 7 is a schematic diagram showing the color-sharing mechanism according to some embodiments of the present disclosure. First, the color-sharing mechanism is considered. When the angular frequency f(P) of the light-emitting units is between 15CPD-30CPD, the color-sharing mechanism may be realized. Therefore, in order to make the red units 11r, the blue units 11b, and the cyan units 11c on the display device may share color to the surrounding green units 11g (as shown by the dotted arrow in FIG. 7), the minimum pitch P_{sub_r} of adjacent two red units 11r, the minimum pitch P_{sub_b} of adjacent two blue units 11b, and the minimum pitch P_{sub_c} of adjacent two cyan units 11b may be adjusted, so that the minimum pitches are all between 15CPD-30CPD. In some embodiments, only the minimum angular frequencies min{f(P_{sub_r}), f(P_{sub_b}), f(P_{sub_c})} of the red unit 11r, the blue unit 11b, and the cyan unit 11c are adjusted to be between 15 CPD-30 CPD. Therefore, the color-sharing mechanism may be expressed as the following relationship (1) in the application of the present disclosure:

15CPD≤min{f(P_{sub_r}),f(P_{sub_b}),f(P_{sub_c})}≤30CPD

Then the visual limit mechanism is considered. When the angular frequency f(P) of the light-emitting units is between 30 CPD and 60 CPD, the visual limit mechanism may be realized. Therefore, in order to make the red units 11r, the blue units 11b, the cyan units 11c, and the green units 11g on the display achieve the light mixing effect, the minimum pitch P_{sub_r} between adjacent red units 11r, the minimum pitch P_{sub_b} between adjacent blue units 11b, the minimum pitch P_{sub_c} between adjacent cyan units 11c, and the minimum pitch P_{sub_g} between adjacent green units 11g are between 30 CPD and 60 CPD. In some embodiments, since the minimum pitch P_{sub_g} between adjacent green units 11g is the smallest in the first direction D1, only the angular frequency f(P_{sub_g}) of the green units 11g is adjusted to be between 30 CPD and 60 CPD. Therefore, the visual limit mechanism may be expressed as the following relationship (2) in the application of the present disclosure:

$$30 CPD \leq f ( {P}_{sub \_ g} ) \leq 60 CPD$$

As mentioned above, in order to satisfy the color-sharing mechanism and the visual limit mechanism at the same time, the minimum pitches of the red units 11r, the blue units 11b, and the cyan units 11c may satisfy relationship (1), and the minimum pitch of the green units 11g may satisfy the relationship (2). In this way, the minimum pitches between the red units 11r, the blue units 11b, the cyan units 11c, and the green units 11g satisfy the following relationship (3) in the present disclosure:

$$\frac{1}{2} \times max \{ {P}_{sub \_ r} , {P}_{sub \_ b} , {P}_{sub \_ c} \} \geq {P}_{sub \_ g} \geq \frac{1}{4} \times max \{ {P}_{sub \_ r} , {P}_{sub \_ b} , {P}_{sub \_ c} \}$$

The present disclosure realizes a light-emitting diode display device 1 having a wide color gamut and excellent display quality by making the quantity and arrangement of the green units 11g, the red units 11r, the blue units 11b, and the cyan units 11c in the display device satisfy the aforementioned mechanism (or relationship). In the following, several specific embodiments and other additional benefits will be provided to make the present disclosure clearer and easier to understand.

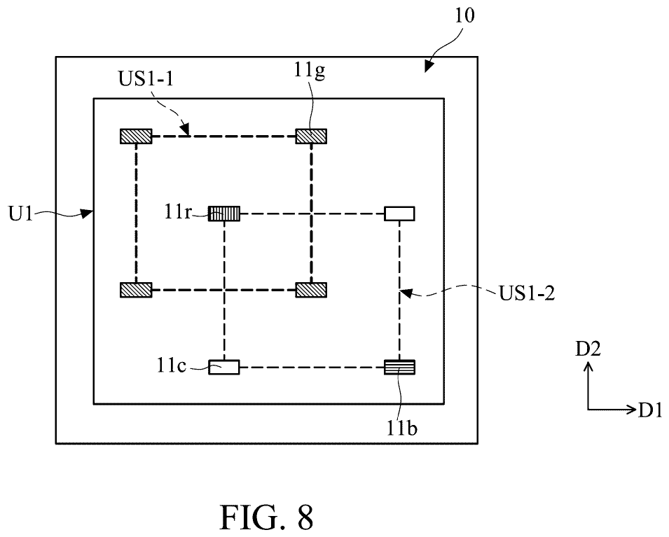

Referring to FIG. 1 and to FIG. 8 at the same time. FIG. 8 is an enlarged schematic diagram of the minimum repeat unit in FIG. 1. As shown in the figure, in some embodiments, the green units 11g, the red units 11r, the blue units 11b, and the cyan units 11c may form a plurality of minimum repeat units U1, and the minimum repeat units U1 are periodically arranged on the substrate 10.

The quantity G of the green units 11g, the quantity R of the red units 11r, the quantity B of the blue units 11b, and the quantity C of the cyan units 11c in each of the minimum repeat units U1 may satisfy G>C≥R≥B to effectively increase the density of pixel information seen by the human eye. Compared with the light-emitting diode display device in which the quantities of light-emitting units of different types are equal, the total quantity of light-emitting units may be reduced while maintaining the display quality by maximizing the quantity G of the green units 11g to reduce the cost. In the embodiments of FIG. 1 and FIG. 8, the minimum repeat unit U1 is a rectangle, but the present disclosure is not limited thereto. In other embodiments, the minimum repeat unit may be a rhombus, a rectangle, a triangle, a polygon, a circle, or other shapes, and at least some of which will be described in detail below.

In some embodiments, the minimum repeat unit U1 has a region area Su, and each of the green unit 11g, the red unit 11r, the blue unit 11b, and the cyan unit 11c respectively has a light-emitting area S_{g}, a light-emitting area Sᵣ, a light-emitting area Se, and a light-emitting area S_{c}. In some embodiments, the light-emitting units of different colors have the same light-emitting area, for example, S_{g}=Sᵣ=Sb=S_{c}. Therefore, the size and luminous efficiency of each light-emitting unit of the light-emitting diode display device 1 disclosed in the present disclosure are the same, so that the lifetime of each light-emitting unit is equivalent, and design difficulties are reduced.

In some embodiments, the proportion of the total light-emitting area of the light-emitting units in the minimum repeat unit U1 is defined as “aperture ratio A”, which may be expressed as the following relationship (4):

$$A = \frac{{GS}_{g} + {RS}_{r} + {BS}_{b} + {CS}_{c}}{Su} < 30 \%$$

The G, R, B, and C respectively are the quantity of green units 11g, the quantity of red units 11r, the quantity of blue units 11b, and the quantity of cyan units 11c in the minimum repeat unit U1. Compared with the liquid crystal display (LCD) whose aperture ratio is designed to be as high as 30% to 90%, the present disclosure may provide a lower aperture ratio A, thereby facilitating maintenance of the light-emitting units in the light-emitting diode display device 1. In some embodiments, the light-emitting diode display device 1 of the present disclosure has an aperture ratio A<30%.

As shown in FIG. 8, the minimum repeat unit U1 in the light-emitting diode display device 1 may be divided into a plurality of spatial sub-units (for example, the spatial sub-unit US1-1 and the spatial sub-unit US1-2) to satisfy the color-sharing mechanism in space. In the present disclosure, the term “spatial sub-unit” refers to the smallest display area spatially related to the color-sharing mechanism, and each spatial sub-unit is composed of at least two units (for example, at least two light-emitting units of the green unit 11g, the red unit 11r, the blue unit 11b, and the cyan unit 11c). For the color-sharing mechanism, each minimum repeat unit U1 includes one spatial sub-unit (hereinafter referred to as the main spatial sub-unit) composed of green units 11g, and another one spatial sub-unit (hereinafter referred to as the color-sharing spatial sub-unit) composed of other light-emitting units (for example, the red unit 11r, the blue unit 11b, and the cyan unit 11c). In some embodiments, the main spatial sub-unit and the color-sharing spatial sub-unit may be partially overlapped to make the effect of the color-sharing mechanism more prominent.

Taking the minimum repeat unit U1 in FIG. 8 as an example, the minimum repeat unit U1 includes the spatial sub-unit US1-1 and the spatial sub-unit US1-2. The spatial sub-unit US1-1 is the main spatial sub-unit composed of four green units 11g. The spatial sub-unit US1-2 is the color-sharing spatial sub-unit composed of two cyan units 11c, one red unit 11r, and one blue unit 11b. Therefore, for the embodiment in FIG. 8, the quantity ratio of the red units 11r, the green units 11g, the blue units 11b, and the cyan units 11c in the minimum repeat unit U1 is 1:4:1:2.

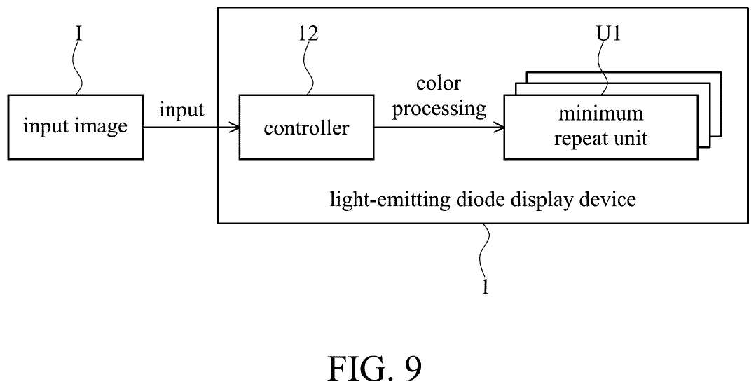

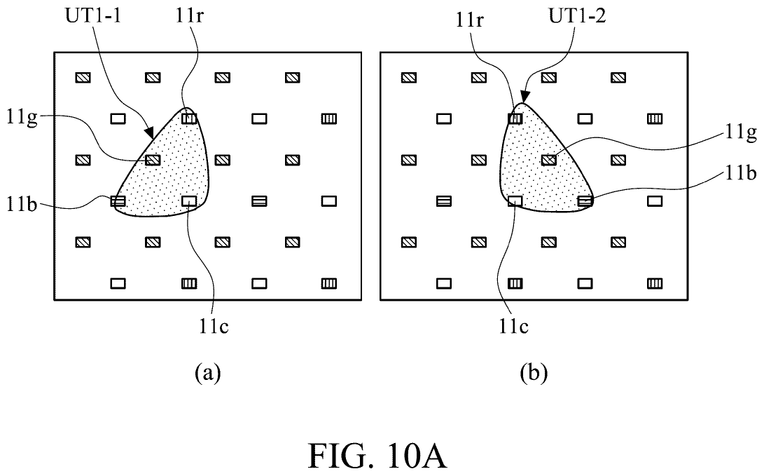

Referring to FIG. 9, which is a schematic diagram showing the operation flow of a light-emitting diode display device according to some embodiments of the present disclosure. As shown in the figure, in some embodiments, the light-emitting diode display device 1 further includes the controller 12, and the controller 12 may perform the color processing on the input image I to improve the display resolution of the light-emitting diode display device 1. Since the ratio of light-emitting units of various colors in the minimum repeat unit U1 is no longer 1:1:1 (R:G:B) similar to that of traditional units, therefore in the application, it is possible to use algorithms in advance for the color processing according to the ratio of each of the units of various colors. Finally, the image information is sent to the light-emitting units in the minimum repeat unit U1 to display an image according to the calculated result. In some embodiments, the algorithm may employ sub-pixel rendering techniques. For example, the color processing includes transforming the input signal V(R, G, B)ᵢₙ into the output signal V(R, G, B, C)ₒᵤₜ using the transformation matrix M, and the matrix transformation equation is V(R, G, B, C)ₒᵤₜ=M·V(R, G, B)ᵢₙ, wherein the V(R, G, B, C)ₒᵤₜ is a 4×1 matrix, M is a 4×3 matrix, and V(R, G, B)ᵢₙ is a 3×1 matrix. The above matrix may be expressed as:

$$[ \begin{matrix}R \\ G \\ B \\ C\end{matrix} ] = [ \begin{matrix}{r}_{1} & {r}_{2} & {r}_{3} \\ {g}_{1} & {g}_{2} & {g}_{3} \\ {b}_{1} & {b}_{2} & {r}_{3} \\ {c}_{1} & {c}_{2} & {c}_{3}\end{matrix} ] \cdot [ \begin{matrix}R \\ G \\ B\end{matrix} ]$$

The left matrix is V(R, G, B, C)ₒᵤₜ, the middle matrix is M, and the right matrix is V(R, G, B)ᵢₙ. The 12 values in M of the matrix transformation equation (that is, r₁-r₃, g₁-g₃, b₁-b₃, and c₁-c₃) represent the transformation factor for converting three-color points of RGB to four-color points of RGBC.

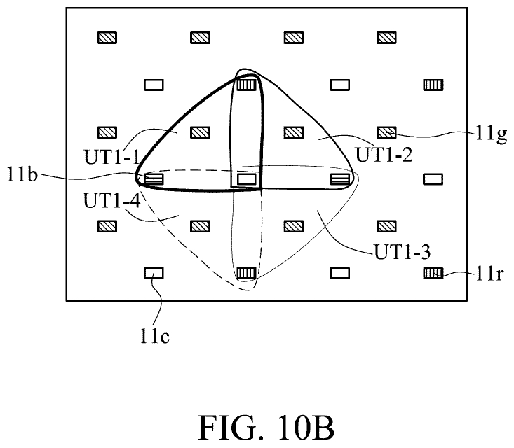

Referring to FIG. 10A and FIG. 10B, which are schematic diagrams showing the temporal sub-unit according to some embodiments of the present disclosure. The light-emitting units may be turned to emit light in turn (for example, by timing control) based on the principle of persistence of vision of the human eye to satisfy the color-sharing mechanism in time and reduce current consumption. In some embodiments, the green units 11g, the red units 11r, the blue units 11b, and the cyan units 11c form a plurality of temporal sub-units, and the controller 12 controls the temporal sub-units to display in turn in a time sequence. In the present disclosure, the term “temporal sub-unit” refers to the smallest display area temporally related to the color-sharing mechanism. It should be noted that each temporal sub-unit is centered on one green unit 11g and make other surrounding units (for example, the red unit 11r, the blue unit 11b, and/or the cyan unit 11c) match the central green unit 11g to satisfy the color-sharing mechanism.

Taking FIG. 10A and FIG. 10B as an example. First, as shown in (a) of FIG. 10A, the temporal sub-unit UT1-1 is turned on. The temporal sub-unit UT1-1 is composed of one green unit 11g as the center and one red unit 11r, one blue unit 11b, and one cyan unit 11c around it. Next, as shown in (b) of FIG. 10A, the time sub-unit UT1-2 is turned on within a time interval that cannot be perceived by the human eye (i.e., the persistence of vision). The temporal sub-unit UT1-2 is composed of another green unit 11g as the center and one red unit 11r, one blue unit 11b, and one cyan unit 11c around it. As shown in FIG. 10B, this step is performed in sequence until the temporal sub-unit UT1-1 to the temporal sub-unit UT1-4 are illuminated as shown in FIG. 10B. For example, the temporal sub-unit UT1-1 to the temporal sub-unit UT1-4 may be turned on in sequence with a time interval of less than 1/16 second, but the present disclosure is not limited thereto.

The light-emitting diode display device of the present disclosure has low energy consumption, low cost, and excellent display effect due to the specific configuration of light-emitting units in space (spatial sub-unit) as mentioned above, as well as by the specific control of light-emitting units in time (temporal sub-unit).

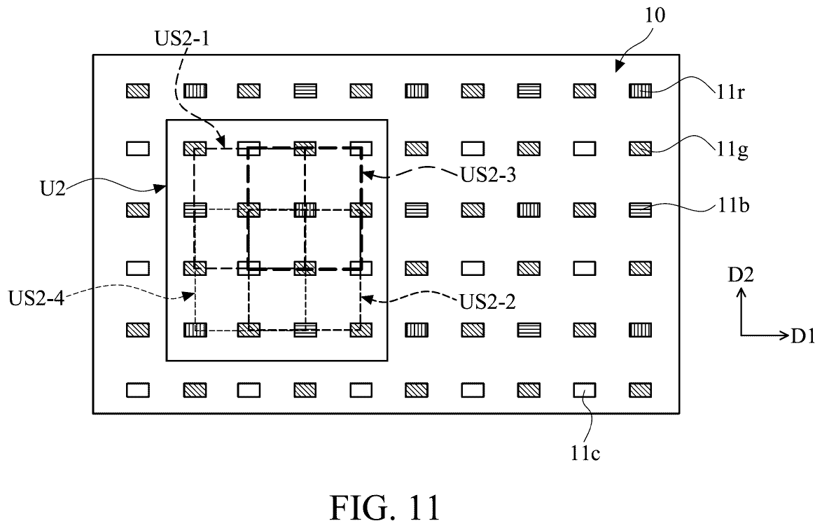

Referring to FIG. 11 to FIG. 15, which respectively are schematic diagrams showing the minimum repeat units and the spatial sub-units of the light-emitting diode display device according to other embodiments of the present disclosure. Compared with the embodiments shown in FIG. 1 and FIG. 8, these embodiments differ in that the light-emitting units are arranged in different ways to form different minimum repeat units and spatial sub-units. In the embodiment of FIG. 11, the minimum repeat unit U2 is a rectangle, which includes eight green units 11g, two red units 11r, two blue units 11b, and four cyan units 11c. Therefore, for the embodiment in FIG. 11, the quantity ratio of the red unit 11r, the green unit 11g, the blue unit 11b, and the cyan unit 11c in the minimum repeat unit U2 is 1:4:1:2. Four of the eight green units 11g form the rectangular spatial sub-unit US2-1, and the other four form the rectangular spatial sub-unit US2-2. Four cyan units 11c form the rectangular spatial sub-unit US2-3, and two red units 11r and two blue units 11b form the rectangular spatial sub-unit US2-4.

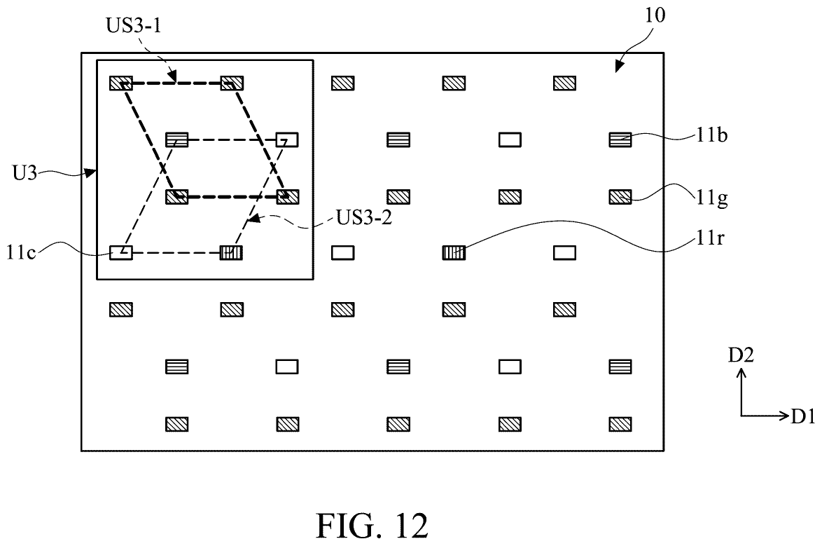

In the embodiment of FIG. 12, the minimum repeat unit U3 is a rectangle, which includes four green units 11g, one red unit 11r, one blue unit 11b, and two cyan units 11c. Therefore, for the embodiment in FIG. 12, the quantity ratio of the red unit 11r, the green unit 11g, the blue unit 11b, and the cyan unit 11c in the minimum repeat unit U3 is 1:4:1:2. Four green units 11g form the parallelogram spatial sub-unit US3-1, and one red unit 11r, one blue unit 11b, and two cyan units 11c form the parallelogram spatial sub-unit US3-2.

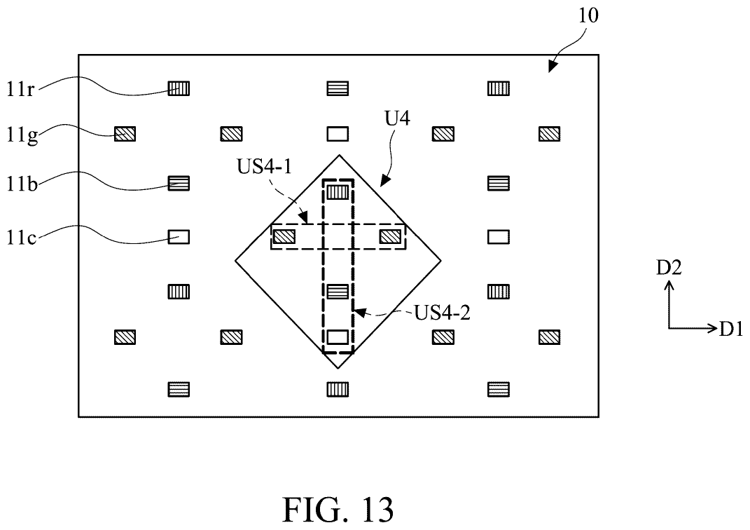

In the embodiment shown in FIG. 13, the minimum repeat unit U4 is a rhombus, which includes two green units 11g, one red unit 11r, one blue unit 11b, and one cyan unit 11c. Therefore, for the embodiment in FIG. 13, the quantity ratio of the red unit 11r, the green unit 11g, the blue unit 11b, and the cyan unit 11c in the minimum repeat unit U4 is 1:2:1:1. Two green units 11g form the rectangular spatial sub-unit US4-1, and one red unit 11r, one blue unit 11b, and one cyan unit 11c form the rectangular spatial sub-unit US4-2.

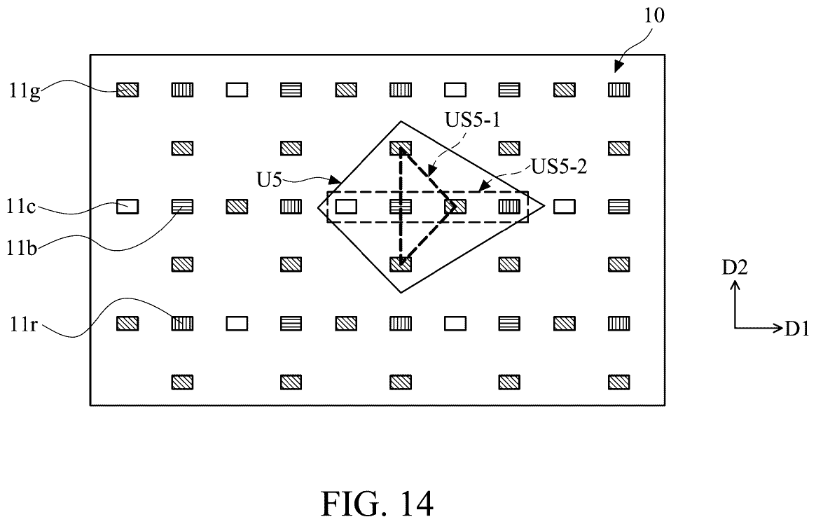

In the embodiment shown in FIG. 14, the minimum repeat unit U5 is a rhombus, which includes three green units 11g, one red unit 11r, one blue unit 11b, and one cyan unit 11c. Therefore, for the embodiment in FIG. 14, the quantity ratio of the red unit 11r, the green unit 11g, the blue unit 11b, and the cyan unit 11c in the minimum repeat unit U5 is 1:3:1:1. Three green units 11g form the triangular spatial sub-unit US5-1, and one red unit 11r, one blue unit 11b, and one cyan unit 11c form the rectangular spatial sub-unit US5-2.

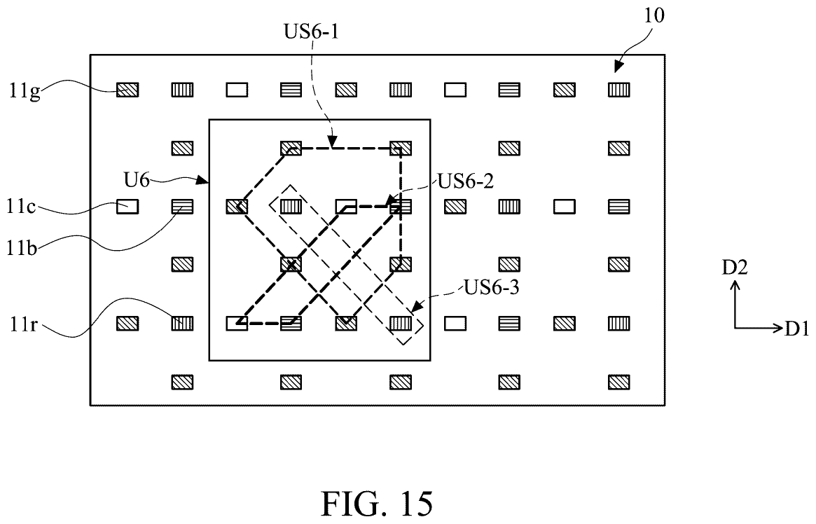

In the embodiment of FIG. 15, the minimum repeat unit U6 is a rectangle, which includes six green units 11g, two red units 11r, two blue units 11b, and two cyan units 11c. Therefore, for the embodiment in FIG. 15, the quantity ratio of the red unit 11r, the green unit 11g, the blue unit 11b, and the cyan unit 11c in the minimum repeat unit U6 is 1:3:1:1. Six green units 11g form the pentagonal spatial sub-unit US6-1, two blue units 11b and two cyan units 11c form the parallelogram spatial sub-unit US6-2, and two red units 11r form the rectangular spatial sub-unit US6-3.

Features in the disclosed embodiments can be mixed and matched arbitrarily as long as they do not violate the spirit of the disclosure or conflict with each other. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A light-emitting diode display device, comprising:
a substrate; and
a plurality of green units, a plurality of red units, a plurality of blue units, and a plurality of cyan units periodically arranged on the substrate;
wherein a quantity of the plurality of green units is more than a quantity of the plurality of red units, the quantity of the plurality of green units is more than a quantity of the plurality of blue units, and the quantity of the plurality of green units is more than a quantity of the plurality of cyan units.

2. The light-emitting diode display device as claimed in claim 1, wherein in a direction, a minimum pitch P_{sub_g} between adjacent two of the plurality of green units is less than a minimum pitch P_{sub_r} between adjacent two of the plurality of red units, the minimum pitch P_{sub_g} between adjacent two of the plurality of green units is less than a minimum pitch P_{sub_b} between adjacent two of the plurality of blue units, and the minimum pitch P_{sub_g} between adjacent two of the plurality of green units is less than a minimum pitch P_{sub_c} between adjacent two of the plurality of cyan units.

3. The light-emitting diode display device as claimed in claim 2, wherein the minimum pitch P_{sub_g} between adjacent two of the plurality of green units, the minimum pitch P_{sub_r} between adjacent two of the plurality of red units, the minimum pitch P_{sub_b} between adjacent two of the plurality of blue units, and the minimum pitch P_{sub_c} between adjacent two of the plurality of cyan units satisfy the following relationship:
$$\frac{1}{2} \times max \{ {P}_{sub \_ r} , {P}_{sub \_ b} , {P}_{sub \_ c} \} \geq {P}_{sub \_ g} \geq \frac{1}{4} \times max \{ {P}_{sub \_ r} , {P}_{sub \_ b} , {P}_{sub \_ c} \} .$$

4. The light-emitting diode display device as claimed in claim 1, wherein the plurality of green units, the plurality of red units, the plurality of blue units, and the plurality of cyan units that are periodically arranged form a plurality of minimum repeat units.

5. The light-emitting diode display device as claimed in claim 4, wherein a quantity G of the plurality of green units, a quantity R of the plurality of red units, a quantity B of the plurality of blue units, and a quantity C of the plurality of cyan units in each of the minimum repeat units satisfy the following relationship:
$$G > C \geq R \geq B .$$

6. The light-emitting diode display device as claimed in claim 4, wherein an aperture ratio of the minimum repeat units is less than 30%.

7. The light-emitting diode display device as claimed in claim 4, wherein a quantity ratio of the plurality of red units, the plurality of green units, the plurality of blue units, and the plurality of cyan units in the minimum repeat units is 1:4:1:2.

8. The light-emitting diode display device as claimed in claim 4, wherein a quantity ratio of the plurality of red units, the plurality of green units, the plurality of blue units, and the plurality of cyan units in the minimum repeat units is 1:2:1:1.

9. The light-emitting diode display device as claimed in claim 4, wherein the quantity ratio of the plurality of red units, the plurality of green units, the plurality of blue units, and the plurality of cyan units in the minimum repeat units is 1:3:1:1.

10. The light-emitting diode display device as claimed in claim 4, wherein each of the plurality of minimum repeat units comprises a plurality of spatial sub-units, wherein each of the plurality of spatial sub-units comprises at least two of the plurality of green units, the plurality of red units, the plurality of blue unit, and the plurality of cyan units.

11. The light-emitting diode display device as claimed in claim 10, wherein the plurality of spatial sub-units in each of the plurality of minimum repeat units partially overlap.

12. The light-emitting diode display device as claimed in claim 10, wherein at least one of the plurality of spatial sub-units is composed of units of the same color.

13. The light-emitting diode display device as claimed in claim 4, further comprising a controller, wherein the controller performs a color processing on an input signal.

14. The light-emitting diode display device as claimed in claim 13, wherein the plurality of green units, the plurality of red units, the plurality of blue units, and the plurality of cyan units form a plurality of temporal sub-units, wherein each of the plurality of temporal sub-units comprises at least one green unit, and the controller controls the temporal sub-units to display in turn in a time sequence.

15. The light-emitting diode display device as claimed in claim 13, wherein the color processing comprises converting an input signal V(R, G, B)ᵢₙ into an output signal V(R, G, B, C)ₒᵤₜ by using a transformation matrix M, and the matrix transformation equation is as follows:
$${V ( R , G , B , C )}_{out} = M \cdot {V ( R , G , B )}_{i n} ,$$
wherein the V(R, G, B, C)ₒᵤₜ is a 4×1 matrix, the M is a 4×3 matrix, and the V(R, G, B)ᵢₙ is a 3×1 matrix.

16. The light-emitting diode display device as claimed in claim 1, wherein each of the plurality of green units comprises a green LED chip, each of the plurality of red units comprises a red LED chip, each of the plurality of blue units comprises a blue LED chip, and each of the plurality of cyan units comprises a cyan LED chip.

17. The light-emitting diode display device as claimed in claim 1, wherein each of the plurality of green units, the plurality of red units, the plurality of blue units, and the plurality of cyan units comprises a blue LED chip or an ultraviolet LED chip and comprises a corresponding color conversion layer disposed on the blue LED chip or the ultraviolet LED chip.

18. The light-emitting diode display device as claimed in claim 1, further comprising a plurality of spacers, wherein the plurality of spacers are disposed between adjacent two of the plurality of green units, the plurality of red units, the plurality of blue units, and the plurality of cyan units, and the plurality of spacers comprise a reflective wall and an absorbing wall disposed on the reflective wall.

19. The light-emitting diode display device as claimed in claim 1, further comprising a distributed Bragg reflector, wherein the distributed Bragg reflector is disposed on the plurality of green units, the plurality of red units, the plurality of blue units, and the plurality of cyan units.
